(19) United States
(12) Patent Application Publication
(10) Pub. No.: US 2025/0275458 A1
(43) Pub. Date: Aug. 28, 2025

(54) Display Device

(71) Applicant: LG Display Co., Ltd., Seoul (KR)

(72) Inventors: Wooyeong Jang, Seoul (KR); KwangSoo Kim, Incheon (KR)

(21) Appl. No.: 19/016,848

(22) Filed: Jan. 10, 2025

(30) Foreign Application Priority Data
Feb. 26, 2024 (KR) 10-2024-0027329

(51) Int. Cl. H10K 77/10; H10K 59/40; H10K 59/80; H10K 102/00

(52) U.S. Cl. CPC H10K 77/111; H10K 59/40; H10K 59/8731; H10K 2102/311

(57) ABSTRACT

A display device includes a substrate which includes a display area, an optical area disposed in the display area and including a through-hole, and a non-display area enclosing the display area, a plurality of organic light emitting diodes on the display area, an encapsulation unit which covers the substrate and the plurality of organic light emitting diodes, a reinforcement member which is disposed on the encapsulation unit and extends to the display area, the non-display area, and the optical area, and a plurality of touch electrodes disposed on the reinforcement member in the display area. Accordingly, propagation of cracks generated from external interference in the optical area is suppressed.

### CROSS-REFERENCE TO RELATED APPLICATION

This application claims the priority of Republic of Korea Patent Application No. 10-2024-0027329 filed on Feb. 26, 2024, which is hereby incorporated by reference in its entirety.

### BACKGROUND

### Field

The present disclosure relates to a display device, and more particularly, to a display device which suppresses cracks generated when a curvature is implemented on a substrate.

### Description of the Related Art

As it enters the information era, a field of a display device which visually expresses electrical information signals has been rapidly developed and studies are continued to improve performances of various display devices, such as a thin-thickness, a light weight, and low power consumption.

A representative display device may include a liquid crystal display device (LCD), a field emission display device (FED), an electro-wetting display device (EWD), and an organic light emitting display device (OLED).

An electroluminescent display device which is represented by an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), it is expected to be utilized in various fields.

### SUMMARY

An object to be achieved by an exemplary embodiment of the present disclosure is to provide a display device including a substrate having a through-hole and a plurality of rounded corner areas.

Another object to be achieved by an exemplary embodiment of the present disclosure is to provide a display device which suppresses cracks generated when a through-hole or a rounded shape (curvature) is implemented on a substrate.

Objects of the present disclosure are not limited to the above-mentioned objects, and other objects, which are not mentioned above, can be clearly understood by those skilled in the art from the following descriptions.

According to the exemplary embodiment of the present disclosure, a display device includes a substrate which includes a display area, an optical area disposed in the display area and including a through-hole, and a non-display area enclosing the display area, a plurality of organic light emitting diodes on the display area, an encapsulation unit which covers the substrate and the organic light emitting diodes, a reinforcement member which is disposed on the encapsulation unit and extends to the display area, the non-display area, and the optical area, and a plurality of touch electrodes disposed on the reinforcement member in the display area.

Other detailed matters of the exemplary embodiments are included in the detailed description and the drawings.

According to the exemplary embodiment of the present disclosure, instead of an inorganic insulating layer disposed on the top of the substrate, a reinforcement member is disposed to manufacture a substrate having a through-hole and a plurality of rounded corner areas.

According to the exemplary embodiment of the present disclosure, instead of an inorganic insulating layer disposed on the top of the substrate of a display device, a reinforcement member is disposed. Therefore, even though a through-hole and a plurality of rounded corner areas are formed using laser in a completing step of a display panel, cracks generated on the top of the display panel and lifting of a dam thereby are suppressed to improve a reliability of the display device.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram for explaining a display device according to an exemplary embodiment of the present disclosure;

FIG. 2 is a view schematically illustrating a circuit configuration of a sub pixel according to an exemplary embodiment of the present disclosure;

FIG. 3 is a plan view of a display device according to an exemplary embodiment of the present disclosure;

FIG. 4 is a cross-sectional view taken along the line IV-IV′ of FIG. 3 according to an exemplary embodiment of the present disclosure;

FIG. 5 is a cross-sectional view taken along the line V-V′ of FIG. 3 of the present disclosure; and

FIG. 6 is a cross-sectional view of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

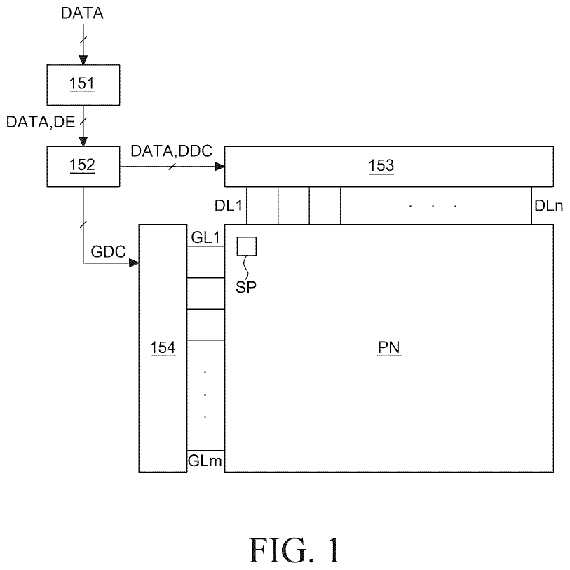

FIG. 1 is a block diagram of a display device according to an exemplary embodiment of the present disclosure.

Referring to FIG. 1, a display device according to exemplary embodiments of the present disclosure includes an image processor 151, a timing controller 152, a data driver 153, a scan driver 154, and a display panel PN.

The image processor 151 (e.g., a circuit) outputs a data enable signal DE together with a data signal DATA supplied from the outside.

Further, for example, the image processor 151 may output one or more of a vertical synchronization signal, a horizontal synchronization signal, and a clock signal in addition to the data enable signal DE.

The timing controller 152 (e.g., a circuit) is supplied with the data signal DATA together with the data enable signal DE or a driving signal including the vertical synchronization signal, the horizontal synchronization signal, and the clock signal from the image processor 151. The timing controller 152 outputs a gate timing control signal GDC for controlling an operation timing of the scan driver 154 and a data timing control signal DDC for controlling an operation timing of the data driver 153, based on the driving signal.

The data driver 153 samples and latches the data signal DATA supplied from the timing controller 152 in response to the data timing control signal DDC supplied from the timing controller 152 to convert the data signal into a gamma reference voltage and output the converted gamma reference voltage. The data driver 153 outputs the data signal DATA through data lines DL1 to DLn. The data driver 153 may be formed as an integrated circuit (IC).

Further, the scan driver 154 (e.g., a circuit) may output the scan signal in response to the gate timing control signal GDC supplied from the timing controller 152. The scan driver 154 may output the scan signal through gate lines GL1 to GLm. The scan driver 154 may be formed as an integrated circuit (IC) or formed in the display panel PN in a gate in panel (GIP) manner.

The display panel PN displays images in response to the data signal DATA and the scan signal supplied from the data driver 153 and the scan driver 154.

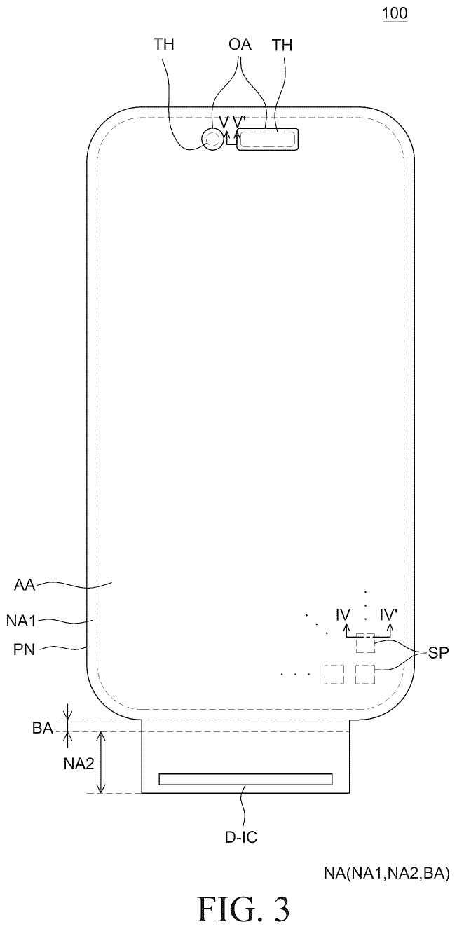

The display panel PN may include a sub pixel SP which displays an image. The display panel PN will be described in detail with reference to FIG. 3 to be described below.

For example, the sub pixel SP includes a red sub pixel, a green sub pixel, and a blue sub pixel or includes a white sub pixel, a red sub pixel, a green sub pixel, and a blue sub pixel. The sub pixel SP has one or more emission areas according to an emission characteristic.

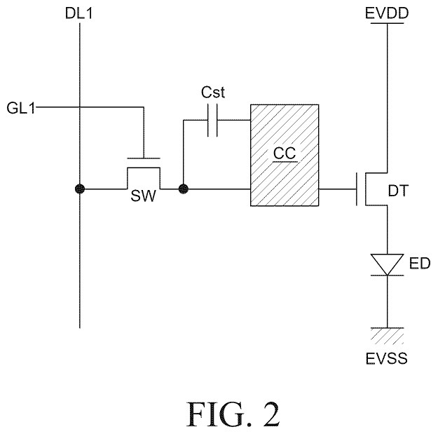

FIG. 2 is a view schematically illustrating a circuit configuration of a sub pixel according to exemplary embodiments of the present disclosure.

Referring to FIG. 2, in one sub pixel, a switching transistor SW, a driving transistor DT, a capacitor Cst, a compensation circuit CC, and an organic light emitting diode ED are included.

For example, the switching transistor SW may perform a switching operation such that a data signal supplied through a first data line DL1 is stored in a capacitor Cst as a data voltage in response to a scan signal supplied through a first gate line GL1. Further, for example, the driving transistor DT operates to flow a driving current between a first power line EVDD (a high potential voltage) and a second power line EVSS (a low potential voltage) in accordance with the data voltage stored in the capacitor Cst. Further, the organic light emitting diode ED may operate to emit light in accordance with a driving current formed by the driving transistor DT.

The compensation circuit CC is a circuit added in the sub pixel to compensate for a threshold voltage of the driving transistor DT. The compensation circuit CC is configured by one or more transistors. The configuration of the compensation circuit CC may vary depending on an external compensating method.

The sub pixel illustrated in FIG. 2 is configured by a 2T (transistor) 1C (capacitor) structure including a switching transistor ST, a driving transistor DT, a capacitor Cst, and a light emitting diode ED. When the compensation circuit CC is added, the sub pixel may be configured in various forms, such as 3T1C, 4T2C, 5T2C, 6T1C, 6T2C, 7T1C, and 7T2C.

FIG. 3 is a plan view of a display device according to an exemplary embodiment of the present disclosure. In FIG. 3, for the convenience of description, among components of the display device 100, the display panel PN and the data driver D-IC are illustrated.

The display panel PN includes a display area AA, an optical area OA which is disposed in the display area AA and includes a through-hole TH, and a non-display area NA which encloses the display area AA. For example, the display panel PN includes a plurality of rounded corner areas. As the display panel PN includes the plurality of rounded corner areas, a bezel area which is a non-display area NA is reduced and the display area AA is maximized.

The display area AA is an area where images are displayed in the display panel PN.

In the display area AA, a plurality of sub pixels SP and a circuit for driving the plurality of sub pixels SP may be disposed. The plurality of sub pixels SP are minimum units which configure the display area AA and a display element may be disposed in each of the plurality of sub pixels SP. For example, an organic light emitting diode which includes an anode, an emission layer, and a cathode may be disposed in each of the plurality of sub pixels SP, but it is not limited thereto. Further, a circuit for driving the plurality of sub pixels SP may include a driving element and a wiring line. For example, the circuit may be configured by a thin film transistor, a storage capacitor, a gate line, and a data line, but is not limited thereto.

The optical area OA is an area which is disposed in the display area AA and has a through-hole TH disposed therein. In the display panel PN, the through-hole TH is disposed in the display area AA to reduce a bezel area which is a non-display area NA and maximize the display area AA. A product with a design which maximizes the display area AA is aesthetically preferable by maximizing the user's screen immersion.

The through-hole TH may be formed so as to correspond to an optical electronic device. The optical electronic device may be a device which receives light which passes through the display panel PN to perform a predetermined function according to received light. Therefore, the optical electronic device may be disposed so as to overlap the through-hole TH of the display panel PN. The optical electronic device may be a camera or various sensors, but is not limited thereto and includes all devices which perform a predetermined function according to light. In the meantime, the optical electronic device is disposed below the display panel PN so that it is not visible to a user. For example, when the optical electronic device is a camera, the camera is disposed on a rear surface of the display panel PN and captures from a front surface of the display device 100, rather than a rear surface.

As illustrated in FIG. 3, two through-holes TH may be provided, but are not limited thereto and through-holes may be disposed in various numbers. For example, one or two through-holes are disposed in the display area AA so that a camera is disposed in a first through-hole and a distance sensing sensor or a face recognition sensor, and a wide-angle camera may be disposed in a second through-hole.

In the non-display area NA, an image is not displayed and various wiring lines and circuits for driving a display element of the display area AA are disposed. For example, in the non-display area NA, a link line which transmits signals to the plurality of sub pixels and circuits of the display area AA, a gate-in-panel (GIP) line, or a driving IC, such as a gate driver or a data driver, may be disposed.

The non-display area NA may be an area extending from the display area AA, but is not limited thereto and may be an area enclosing the display area AA. As illustrated in FIG. 3, the non-display area NA may have a shape which encloses the display area AA with the same shape as the display area AA and for example, may have a shape having a rounded corner.

The non-display area NA includes a first non-display area NA1, a bending area BA, and a second non-display area NA2. The first non-display area NA1 is an area which encloses the display area AA and extends from the display area AA. The bending area BA may extend from one side of the first non-display area NA1 and may be bent. The second non-display area NA2 is an area which extends from the bending area BA to be disposed below the display area AA.

The first non-display area NA1 and the second non-display area NA2 are disposed on the same plane as the display area AA or disposed to be parallel to the display area AA and maintain a flat state. For example, the first non-display area NA1 is disposed to be flat on the same plane as the display area AA and the second non-display area NA2 is disposed below the display area AA to be parallel to the display area AA and be flat. Therefore, the display area AA, the first non-display area NA1, and the second non-display area NA2 may be referred to as non-bending areas, but are not limited thereto.

In the second non-display area NA2, a driving IC D-IC may be disposed. The driving IC D-IC is a data driver which supplies a data signal to the plurality of sub pixels SP. For example, in the second non-display area NA2 in which the driving IC D-IC is disposed, a pad unit is disposed and a printed circuit board which is electrically connected to the pad unit is further disposed to supply a signal to the driving IC D-IC, but is not limited thereto.

In the meantime, the driving IC D-IC is disposed on one side of the display panel PN in a chip on panel (COP) manner to be connected to the display panel PN or is disposed in a separate flexible film to be connected to the display panel PN in a chip on film (COF) manner, but is not limited thereto.

As the display panel PN is bent, the driving IC D-IC disposed in the second non-display area NA2 is disposed below the display area AA. For example, the driving IC D-IC and the printed circuit board connected to the pad unit of the display panel PN move to the rear surface of the display panel PN and overlap the display area AA. Therefore, as seen from the top of the display panel PN, circuit elements, such as the driving IC D-IC and the printed circuit board may not be visible. Accordingly, the size of the non-display area NA which is visible from the top of the display panel PN is reduced to implement a narrow bezel.

The display device 100 may further include various additional elements to generate various signals or drive the pixel in the display area AA. The additional elements for driving the pixels may include an inverter circuit, a multiplexer, or an electrostatic discharge (ESD) circuit. The display device 100 may further include an additional element associated with a function other than a function of driving a pixel. For example, the display device 100 may include additional elements which provide a touch sensing function, a user authentication function (for example, fingerprint recognition), a multilevel pressure sensing function, or a tactile feedback function. The above-mentioned additional elements may be located in an external circuit which is connected to the non-display area NA and/or the connecting interface.

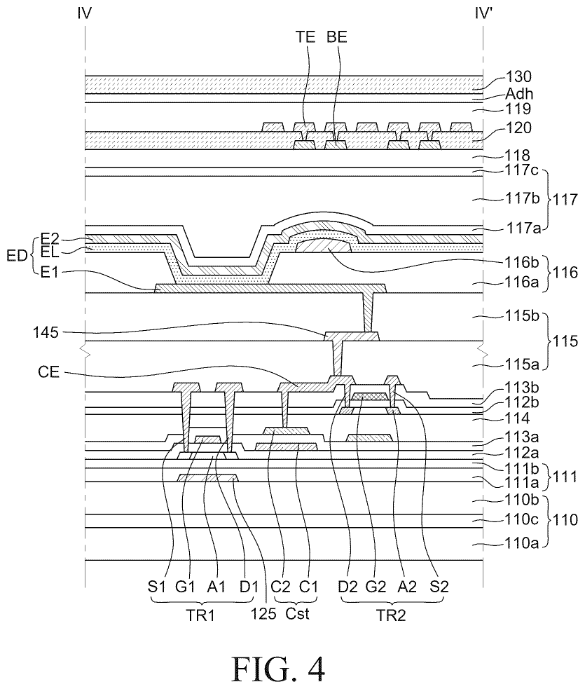

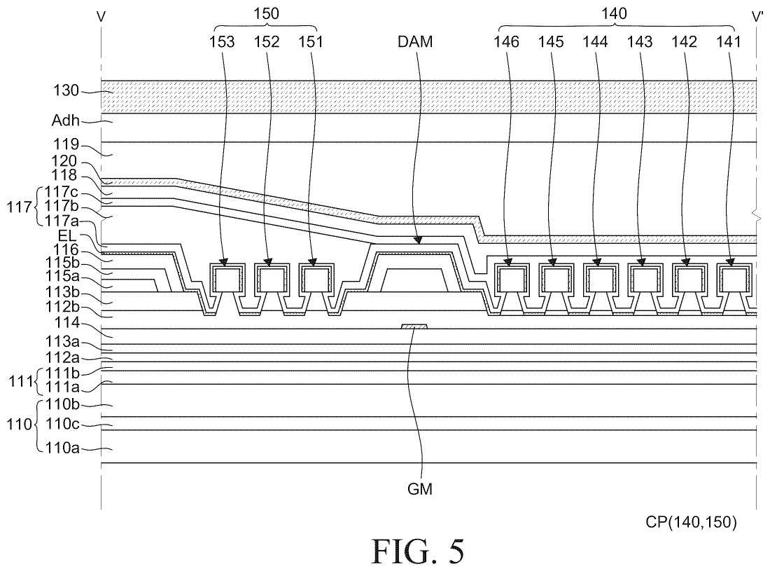

Hereinafter, a cross-sectional structure of the display device 100 will be described in more detail with reference to FIGS. 4 and 5 together.

FIG. 4 is a cross-sectional view taken along the line IV-IV′ of FIG. 3 according to one embodiment. FIG. 5 is a cross-sectional view taken along the line V-V′ of FIG. 3 according to one embodiment.

Referring to FIGS. 3, 4, and 5 together, the display device 100 according to the exemplary embodiment of the present disclosure includes a display panel PN, an adhesive layer Adh, and a polarization layer 130.

The display panel PN includes a substrate 110, a first buffer layer 111, a first thin film transistor TR1, a second thin film transistor TR2, a first gate insulating layer 112a, a first interlayer insulating layer 113a, a second buffer layer 114, a second gate insulating layer 112b, a second interlayer insulating layer 113b, a connection electrode CE, a first planarization layer 115a, a second planarization layer 115b, an auxiliary electrode 145, a bank 116a, a spacer 116b, an anode E1, an emission layer EL, a cathode E2, an encapsulation unit 117, a touch electrode TE, an organic layer 118, a reinforcement member 120, and a protective layer 119.

The substrate 110 serves to support and protect components of a flexible display device disposed there above.

The substrate 110 is a component for supporting various components included in the display device 100 and may be formed of an insulating material. The substrate 110 includes a first substrate 110a, a second substrate 110b, and an interlayer insulating film 110c. The interlayer insulating film 110c may be disposed between the first substrate 110a and the second substrate 110b. As described above, the substrate 110 is configured by the first substrate 110a, the second substrate 110b, and the interlayer insulating film 110c to suppress the moisture permeation. For example, the first substrate 110a and the second substrate 110b may be polyimide (PI) substrates and the interlayer insulating film 110c may be formed of a single layer of silicon nitride (SiNx) or silicon oxide (SiOx) or multiple layers thereof.

A light shielding layer 125 is disposed on the substrate 110.

The first buffer layer 111 is disposed on the substrate 110 while covering the light shielding layer 125. Specifically, a multi-buffer layer 111a is disposed on the substrate 110 while covering the light shielding layer 125 and an active buffer layer 110b is disposed on the multi-buffer layer 111a.

The multi-buffer layer 111a delays diffusion of the moisture or oxygen permeating the substrate 110 and includes at least any one of silicon nitride (SiNx) and silicon oxide (SiOx).

The active buffer layer 111b protects a first active layer A1 and blocks various types of defects introduced from the substrate 110. For example, the active buffer layer 111b includes at least any one of a-Si, silicon nitride (SiNx), and silicon oxide (SiOx).

The first thin film transistor TR1 may be disposed on the first buffer layer 111. The first thin film transistor TR1 may include a first active layer A1, a first gate electrode G1, a first source electrode S1, and a first drain electrode D1. Here, depending on the design of the pixel circuit, the first source electrode S1 may serve as a first drain electrode and the first drain electrode D1 may serve as a first source electrode.

The first active layer A1 is disposed on the first buffer layer 111 so as to overlap the light shielding layer 125. The first active layer A1 may include amorphous silicon or polycrystalline silicon. For example, the first active layer A1 may include a low-temperature polycrystalline silicon LTPS. For example, the polycrystalline silicon material has a high mobility (100 cm2/Vs or higher) so that energy power consumption is low and reliability is excellent. Therefore, the polysilicon material may be applied to a gate driver for driving elements which drive thin film transistors for a display element and/or a multiplexer (MUX) and also applied as an active layer A2 of a driving thin film transistor of the display device 100 according to the exemplary embodiment of the present disclosure, but is not limited thereto. For example, the polycrystalline silicon material may also be applied as the active layer A1 of the switching thin film transistor according to the characteristic of the display device 100. An amorphous silicon (a-Si) material is deposited on the first buffer layer 111 and a dehydrogenation process and a crystallization process are performed to form polycrystalline silicon and the polycrystalline silicon is patterned to form the first active layer A1. Here, the first active layer A1 includes a first channel region in which a channel is formed when the first thin film transistor TR1 is driven and a first source region and a first drain region on both sides of the first channel region. The first source region refers to a part of the first active layer A1 which is connected to the first source electrode S1 and the first drain region refers to a part of the first active layer A1 which is connected to the first drain electrode D1. For example, the first source region and the first drain region are configured by ion-doping (impurity doping) of the first active layer A1. The first source region and the first drain region may be generated by doping ions into the polycrystalline silicon material and the first channel region may refer to a part in which the ions are not doped, but the polycrystalline silicon material remains.

The first gate insulating layer 112a is disposed on the first active layer A1. The first gate insulating layer 112a may be configured by a single layer of silicon nitride (SiNx) or silicon oxide (SiOx) or a multilayer thereof. In the first gate insulating layer 112a, a contact hole through which the first source electrode S1 and the first drain electrode D1 of the first thin film transistor TR1 are connected to the first source region and the first drain region of the first active layer A1 of the first thin film transistor TR1, respectively, may be formed.

The first gate electrode G1 of the first thin film transistor TR1 and a first capacitor electrode C1 of the storage capacitor Cst may be disposed on the first gate insulating layer 112a.

At this time, the first gate electrode G1 and the first capacitor electrode C1 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The first gate electrode G1 may be formed on the first gate insulating layer 112a so as to overlap the first channel region of the first active layer A1 of the first thin film transistor TR1.

The first capacitor electrode C1 may be omitted based on a driving characteristic of the display device 100 and a structure and a type of the thin film transistor. The first gate electrode G1 and the first capacitor electrode C1 may be formed by the same process. Further, the first gate electrode G1 and the first capacitor electrode C1 may be formed of the same material on the same layer.

The first interlayer insulating layer 113a may be disposed above the first gate insulating layer 112a, the first gate electrode G1, and the first capacitor electrode C1. The first interlayer insulating layer 113a may be configured by a single layer of silicon nitride (SiNx) or silicon oxide (SiOx) or a multilayer thereof. In the first interlayer insulating layer 113a, a contact hole for exposing the first source region and the first drain region of the first active layer A1 of the first thin film transistor TR1 may be formed.

A second capacitor electrode C2 of the storage capacitor Cst may be disposed on the first interlayer insulating layer 113a. The second capacitor electrode C2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 may be formed on the first interlayer insulating layer 113a so as to overlap the first capacitor electrode C1. Further, the second capacitor electrode C2 may be formed of the same material as the first capacitor electrode C1. The second capacitor electrode C2 may be omitted based on a driving characteristic of the display device 100 and a structure and a type of the thin film transistor.

The second buffer layer 114 may be disposed on the first interlayer insulating layer 113a and the second capacitor electrode C2. The second buffer layer 114 may be configured by a single layer of silicon nitride (SiNx) or silicon oxide (SiOx) or a multi-layer thereof. A contact hole for exposing the first source region and the first drain region of the first active layer A1 of the first thin film transistor TR1 may be formed in the second buffer layer 114. Further, in the second buffer layer 114, a contact hole for exposing the second capacitor electrode C2 of the storage capacitor Cst may be formed.

The second buffer layer 114 may be formed by a multiple layer, but is not limited thereto.

The second active layer A2 of the second thin film transistor TR2 may be disposed on the second buffer layer 114. Here, the second thin film transistor TR2 may include a second active layer A2, a second gate insulating layer 112b, a second gate electrode G2, a second source electrode S2, and a second drain electrode D2. Here, depending on the design of the pixel circuit, the second source electrode S2 may serve as a drain electrode and the second drain electrode D2 may serve as a source electrode.

Further, the second active layer A2 includes a second channel region in which a channel is formed when the second thin film transistor TR2 is driven and a second source region and a second drain region on both sides of the second channel region. The second source region refers to a part of the second active layer A2 which is connected to the second source electrode S2 and the second drain region refers to a part of the second active layer A2 which is connected to the second drain electrode D2.

The second active layer A2 may be formed of an oxide semiconductor. The oxide semiconductor material has a larger band gap as compared with a silicon material so that electrons may not jump over the band gap in an off state. Therefore, the oxide semiconductor material has a low off-current. Therefore, the thin film transistor including an active layer which is formed of an oxide semiconductor is suitable for a switching thin film transistor which maintains on-time to be short and off-time to be long, but is not limited thereto. Depending on the characteristic of the display device 100, the oxide semiconductor may be applied as a driving thin film transistor. Further, due to the small off-current, a magnitude of an auxiliary capacitance may be reduced so that the oxide semiconductor may be appropriate for a high-resolution display element. For example, the second active layer A2 may be formed of metal oxide and for example, may be formed of various metal oxide such as indium-gallium-zinc-oxide (IGZO). Here, the description was made under the assumption that the second active layer A2 of the second thin film transistor TR2 is configured by IGZO, among various metal oxides, but it is not limited thereto. Therefore, the second active layer A2 may be formed of another metal oxide such as indium-zinc-oxide (IZO), indium-gallium-tin-oxide (IGTO), or indium-gallium-oxide (IGO), rather than IGZO.

The second active layer A2 may be formed by depositing the metal oxide on the second buffer layer 114, performing a heat treatment for stabilization, and then patterning the metal oxide.

The second gate insulating layer 112b may be disposed on the entire substrate 110 including the second active layer A2. For example, the second gate insulating layer 112b may be configured by a single layer of silicon nitride (SiNx) or silicon oxide (SiOx) or a multilayer thereof.

The second gate electrode G2 may be disposed on the second gate insulating layer 112b.

The second gate electrode G2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material may be used.

The second interlayer insulating layer 113b is disposed on the second gate insulating layer 112b and the second gate electrode G2. A contact hole for exposing the first active layer A1 of the first thin film transistor TR1 and the second active layer A2 of the second thin film transistor TR2 may be formed in the second interlayer insulating layer 113b. For example, a contact hole for exposing the first source region and the first drain region of the first active layer A1 of the first thin film transistor TR1 may be formed in the second interlayer insulating layer 113b. A contact hole for exposing the second source region and the second drain region of the second active layer A2 of the second thin film transistor TR2 may be formed in the second interlayer insulating layer 113b.

The second interlayer insulating layer 113b may be configured as a single layer of silicon nitride (SiNx) or silicon oxide (SiOx) or a multi-layer thereof.

A connection electrode CE, the first source electrode S1 and the first drain electrode D1 of the first thin film transistor TR1 and the second source electrode S2 and the second drain electrode D2 of the second thin film transistor TR2 may be disposed on the second interlayer insulating layer 113b.

The connection electrode CE may be electrically connected to the second drain electrode D2 of the second thin film transistor TR2. Further, the connection electrode CE may be electrically connected to the second capacitor electrode C2 of the storage capacitor Cst through the contact holes formed in the second buffer layer 114 and the second interlayer insulating layer 113b. That is, the connection electrode CE may serve to electrically connect the second capacitor electrode C2 of the storage capacitor Cst and the second drain electrode D2 of the second thin film transistor TR2 to each other.

Here, the first source electrode S1 and the first drain electrode D1 of the first thin film transistor TR1 may be connected to the first active layer A1 of the first thin film transistor TR1 through the contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 may be connected to the second active layer A2 through the contact hole formed in the second interlayer insulating layer 113b.

The connection electrode CE, the first source electrode S1 and the first drain electrode D1 of the first thin film transistor TR1 and the second source electrode S2 and the second drain electrode D2 of the second thin film transistor TR2 may be formed of the same material by the same process.

For example, the connection electrode CE, the first source electrode S1 and the first drain electrode D1 of the first thin film transistor TR1 and the second source electrode S2 and the second drain electrode D2 of the second thin film transistor TR2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. For example, the connection electrode CE, the first source electrode S1 and the first drain electrode D1 of the first thin film transistor TR1 and the second source electrode S2 and the second drain electrode D2 of the second thin film transistor TR2 may be formed of a triple layered structure of titanium (Ti)/aluminum (Al)/titanium (Ti), but are not limited thereto.

The connection electrode CE may be integrally formed to be connected to the second drain electrode D2 of the second thin film transistor TR2, but is not limited thereto.

The first planarization layer 115a may be disposed on the connection electrode CE, the first source electrode S1 and the first drain electrode D1 of the first thin film transistor TR1, the second source electrode S2 and the second drain electrode D2 of the second thin film transistor TR2, and the second interlayer insulating layer 113b.

The first planarization layer 115a may be an organic layer which planarizes and protects upper portions of the first thin film transistor TR1 and the second thin film transistor TR2. For example, the first planarization layer 115a may be formed of an organic material such as acryl resin, epoxy resin, phenolic resin, polyamide resin, or polyimide resin.

The auxiliary electrode 145 may be disposed on the first planarization layer 115a. The auxiliary electrode 145 may be connected to the second drain electrode D2 of the second thin film transistor TR2 through the contact hole of the first planarization layer 115a. The auxiliary electrode 145 may serve to electrically connect the second thin film transistor TR2 and the anode E1 with each other. The auxiliary electrode 145 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The auxiliary electrode 145 may be formed of the same material as the second source electrode S2 and the second drain electrode D2 of the second thin film transistor TR2.

The second planarization layer 115b may be disposed above the auxiliary electrode 145 and the first planarization layer 115a. For example, the second planarization layer 115b may be formed of an organic material, such as acryl resin, epoxy resin, phenolic resin, polyamide resin, or polyimide resin.

The light emission diode ED is disposed on the second planarization layer 115b.

The anode E1 is disposed on the second planarization layer 115b. At this time, the anode E1 may be electrically connected to the auxiliary electrode 145 through the contact hole provided in the second planarization layer 115b. The anode E1 is formed of a metallic material.

When the display device 100 is a top emission type in which light emitted from the light emitting diode ED is emitted above the substrate SUB on which the light emitting diode ED is disposed, the anode E1 may further include a transparent conductive layer and a reflective layer on the transparent conductive layer. The transparent conductive layer may be formed of transparent conductive oxide such as ITO or IZO and the reflective layer is formed of silver (Ag), aluminum (Al), gold (Au), molybdenum (Mo), tungsten (W), chrome (Cr), or an alloy thereof.

The bank 116a may be disposed while covering the anode E1. A part of the bank 116a corresponding to an emission area of the sub pixel may be open. A part of the anode E1 may be exposed through the open part of the bank 116a (hereinafter, referred to as an open area). At this time, the bank 116a may be formed of an inorganic insulating material, such as silicon nitride (SiNx) or silicon oxide (SiOx), or an organic insulating material, such as benzocyclobutene resin, acrylic resin or imide resin, but is not limited thereto. The spacer 116b may be further disposed on the bank 116a.

The emission layer EL may be disposed in the open area of the bank 116a and in the vicinity of the open area of the bank. Therefore, the emission layer EL may be disposed on the anode E1 exposed through the open area of the bank 116a.

The cathode E2 may be disposed on the emission layer EL.

The light emitting diode ED may be formed by the anode E1, the emission layer EL, and the cathode E2. The emission layer EL may include a plurality of organic films.

The encapsulation unit 117 is located on the above-described light emitting diode ED.

The encapsulation unit 117 may have a single layer structure or a multi-layered structure. For example, the encapsulation unit 117 may include a first encapsulation layer 117a, a second encapsulation layer 117b, and a third encapsulation layer 117c.

At this time, the first encapsulation layer 117a and the third encapsulation layer 117c are configured by inorganic films and the second encapsulation layer 117b is configured by an organic film. Among the first encapsulation layer 117a, the second encapsulation layer 117b, and the third encapsulation layer 117c, the second encapsulation layer 117b is the thickest and serves as a planarization layer.

The first encapsulation layer 117a is disposed on the cathode E2 and is disposed to be the most adjacent to the light emitting diode ED. The first encapsulation layer 117a is formed of an inorganic insulating material on which low-temperature deposition may be performed. For example, the first encapsulation layer 117a is configured by silicon nitride (SiNx), silicon oxide (SiOx), silicon oxynitride (SiON), or aluminum oxide (Al2O3). The first encapsulation layer 117a is deposited under a low temperature atmosphere so that during the deposition process, the damage of the light emitting layer EL including an organic material which is vulnerable to the high temperature atmosphere may be suppressed.

The second encapsulation layer 117b may be formed to have a smaller area than that of the first encapsulation layer 117a. In this case, the second encapsulation layer 117b may be formed to expose both ends of the first encapsulation layer 117a. The second encapsulation layer 117b may serve as a buffer to alleviate stress between the layers due to bending of the flexible display device and to enhance planarization performance.

For example, the second encapsulation layer 117b is formed of an organic insulating material, such as acrylic resin, epoxy resin, polyimide, polyethylene, or silicon oxy carbon (SiOC). For example, the second encapsulation layer 117b may be formed by an inkjet method, but is not limited thereto.

The third encapsulation layer 117c may be formed above the substrate 110 on which the second encapsulation layer 117b is formed so as to cover upper surfaces and side surfaces of the second encapsulation layer 117b and the first encapsulation layer 117a. At this time, the third encapsulation layer 117c may minimize or block the permeation of external moisture or oxygen into the first encapsulation layer 117a and the second encapsulation layer 117b. For example, the third encapsulation layer 117c is configured by an inorganic insulating material, such as silicon nitride (SiNx), silicon oxide (SiOx), silicon oxynitride (SiON), or aluminum oxide (Al2O3).

In the meantime, a dam DAM which blocks the flow of the second encapsulation layer 117b which configures the encapsulation unit 117 may be disposed in the non-display area NA. Specifically, the dam DAM is disposed as a closed curve which encloses the display area AA in the first non-display area NA1. For example, the first encapsulation layer 117a and the third encapsulation layer 117c are disposed on the dam DAM and the flow of the second encapsulation layer 117b is blocked by the dam DAM. The dam DAM needs to be formed with a predetermined height or higher to block the flow of the second encapsulation layer 117b. To this end, the dam DAM may be formed of at least one or more layers formed of an organic material. For example, the dam DAM may include a bottom layer formed of the same material as the second interlayer insulating layer 113b, an intermediate layer formed of the same material as the second planarization layer 115b, and a top layer formed of the same material as the bank 116a, but is not limited thereto. Even though in the drawing, a configuration with one dam DAM is illustrated, two or more dams DAM may also be provided.

Referring to FIGS. 3 and 5 together, the dam DAM may be disposed in a closed curve shape which encloses the through-hole TH not only in the first non-display area NA, but also in the optical area OA. The optical area OA includes the through-hole TH and an area in which a connection prevention unit CP which encloses the through-hole TH and the dam DAM are disposed. For example, the connection prevention unit CP and the dam DAM are disposed in a closed loop shape around the through-hole TH. The connection prevention unit CP and the dam DAM are disposed in a closed loop. This is because if any a part is open, the moisture and oxygen may permeate the display area AA from the outside or on the contrary, the second encapsulation layer 117b may overflow from the inside into the optical area OA and further into the through-hole TH.

The connection prevention unit CP includes a first prevention unit 140 and a second prevention unit 150. The first prevention unit 140, the dam DAM, and the second prevention unit 150 are sequentially disposed around the through-hole TH. The connection prevention unit CP is formed to disconnect the emission layer EL to suppress the permeation of moisture or oxygen. Referring to FIG. 5, the first prevention unit 140 is disposed to be close to the through-hole TH and then the dam DAM and the second prevention unit 150 are sequentially disposed. The first prevention unit 140 and the second prevention unit 150 may be disposed to protect the light emitting diode ED of the display area AA from moisture or oxygen which may be introduced from the through-hole TH. The emission layer EL of the light emitting diode ED is deposited on the front surface of the display panel PN and is also uniformly deposited in the optical area OA. The emission layer EL is highly reactive and dispersive to moisture and oxygen due to the nature of the organic material to well transmit moisture and oxygen to the light emitting diode ED of the display area AA. In order to suppress this, the emission layer EL may be partially disconnected by the first prevention unit 140 and the second prevention unit 150. In the present specification, two prevention units are illustrated, but are not limited thereto.

The first prevention unit 140 includes a first structure 141, a second structure 142, a third structure 143, a fourth structure 144, a fifth structure 145, and a sixth structure 146. The first structure 141 to the sixth structure 146 may be configured to have two-stage structure with an upper portion and a lower portion to disconnect the emission layer EL which may become a moisture permeation path from the area in which the through-hole TH is disposed. Further, an under-cut structure may be formed on an upper side surface. Specifically, the upper portions of the first structure 141 to the sixth structure 146 are disposed to have a rectangular cross-section which is close to the right angle and the lower portions are disposed to have a trapezoidal cross-section with sides which is regularly tapered. Therefore, there may be a difference in a width on a bottom surface of the upper portion and a top surface of the lower portion at which the upper portion and the lower portion meet. The top surface of the lower portion is formed to be narrower than the bottom surface of the upper portion so that an undercut structure in which a part of the bottom surface of the upper portion is exposed may be formed. By doing this, the emission layer EL deposited on the front surface of the display panel PN may be disconnected by the undercut structure of the upper side surfaces of the first structure 141 to the sixth structure 146 as described above.

The first structure to the sixth structure 141, 142, 143, 144, 145, and 146 which configure the first prevention unit 140 may be formed of organic material and an inorganic material. For example, the upper portions of the first structure to the sixth structure 141, 142, 143, 144, 145, and 146 may be formed by the same material as the second planarization layer 115b, but are not limited thereto. For example, the lower portions of the first structure to the sixth structure 141, 142, 143, 144, 145, and 146 may be formed by the same material as the second interlayer insulating layer 113b, but are not limited thereto.

The second prevention unit 150 includes a seventh structure 151 to a ninth structure 153. The seventh structure 151 to the ninth structure 153 which configure the second prevention unit 150 may be formed with the two-stage structure including an upper portion and a lower portion, like the first structure 141 to the sixth structure 146. The second encapsulation layer 117b disposed on the second prevention unit 150 makes it difficult for moisture or oxygen to permeate the upper portion. In order to block the path mainly penetrating through the side portion where the through-hole TH or the first prevention unit 140 is disposed, an undercut structure may be formed on the upper side surface, like the first prevention unit 140. The first prevention unit 140 and the second prevention unit 150 are disposed so that the moisture or the oxygen permeating into the light emitting diode 120 of the display area AA through the emission layer EL in the optical area OA may be suppressed.

The seventh structure to the ninth structure 151, 152, 153 which configure the second prevention unit 150 may also be formed of organic material and an inorganic material. For example, the upper portions of the seventh structure to the ninth structure 151, 152, 153 may be formed by the same material as the second planarization layer 115b, but are not limited thereto. Further, the lower portions of the seventh structure to the ninth structure 151, 152, 153 may be formed by the same material as the second interlayer insulating layer 113b, but are not limited thereto.

Referring to FIGS. 4 and 5, an organic layer 118 may be disposed on the third encapsulation layer 117c. The organic layer 118 may be formed of an organic material, such as acryl resin, epoxy resin, phenolic resin, polyamide resin, and polyimide resin. The step of the components of the display panel PN disposed below the organic layer 118 is suppressed by the organic layer 118 to improve the visibility of the display device.

The touch sensing unit may be disposed on the organic layer 118. Specifically, the touch sensing unit includes a bridge electrode BE disposed on the organic layer 118, a reinforcement member 120 disposed on the bridge electrode BE, and a plurality of touch electrodes TE disposed on the reinforcement member 120.

The plurality of touch electrodes TE includes a plurality of first touch electrodes extending in a first direction and a plurality of second touch electrodes extending in a second direction intersecting the first direction.

For example, the plurality of first touch electrodes and the plurality of second touch electrodes may be disposed on the same layer. However, in the intersecting areas of the plurality of first touch electrodes and the plurality of second touch electrodes, the plurality of second touch electrodes is separately disposed and the plurality of separated second touch electrodes are connected by the bridge electrode BE.

The reinforcement member 120 is disposed between the plurality of second touch electrodes and the bridge electrode BE. The reinforcement member 120 may remove the step at the location where the plurality of touch electrodes TE are disposed and electrically insulates the plurality of second touch electrodes and the bridge electrode BE.

The reinforcement member 120 may be an adhesive layer or an organic layer including a polymer material. For example, the reinforcement member 120 may be a pressure sensitive adhesive (PSA) or polyimide (PI). As the reinforcement member 120 which is a flexible material is disposed at the top of the display panel PN, cracks at the top layer of the display panel PN due to the external force may be suppressed.

In the display device 100 according to the exemplary embodiment of the present disclosure, when the pressure sensitive adhesive (PSA) is used as the reinforcement member 120, the reinforcement member 120 extends from the display area AA to cover the dam DAM disposed in the non-display area NA. The reinforcement member 120 may be disposed to extend from the display area AA to the non-display area NA and for example, one end of the reinforcement member 120 extends to one end of the substrate 110. When the pressure sensitive adhesive is used as the reinforcement member 120, the pressure sensitive adhesive does not serve as a movement path of the moisture so that the pressure sensitive adhesive may extend from the non-display area NA to one end of the display panel PN. Further, when the pressure sensitive adhesive is used as the reinforcement member 120, the pressure sensitive adhesive has a flexibility and a high thermal expansion coefficient. Therefore, if an external force is applied to the top layer of the display panel PN, the pressure sensitive adhesive is deformed to serve as a buffer layer which absorbs stress. Accordingly, the stress caused by the external force is suppressed from being applied to the display panel PN.

Further, in the display device 100 according to the exemplary embodiment of the present disclosure, when the pressure sensitive adhesive (PSA) is used as the reinforcement member 120, the reinforcement member 120 is disposed to extend from the display area AA to cover the dam DAM disposed in the optical area OA. For example, one end of the reinforcement member 120 extends from the display area AA to the through-hole TH. The pressure sensitive adhesive has a flexibility and a high thermal expansion coefficient so that if an external force is applied to the top layer of the display panel PN, the pressure sensitive adhesive is deformed to serve as a buffer layer which absorbs stress. Accordingly, the stress caused by the external force is suppressed from being applied to the display panel PN.

The protective layer 119 is disposed so as to cover the plurality of touch electrodes TE. The protective layer 119 may include an organic insulating layer. For example, the protective layer 119 may be formed of an organic material, such as acryl resin, epoxy resin, phenolic resin, polyamide resin, or polyimide resin.

The protective layer 119 which is formed of an organic material is disposed on the top layer of the display panel PN to suppress cracks generated on the top layer of the display panel due to the external force. Further, the step at the top layer of the display panel PN is suppressed by the protective layer 119 to improve the visibility of the display device.

In the meantime, the polarization layer 130 is disposed on the display panel PN.

The polarization layer 130 suppresses reflection of external light on the display area AA of the substrate 110. When the display device 100 is used at the outside, external natural light enters to be reflected by a reflective layer included in the anode E1 of the light emitting diode ED or reflected by an electrode which is formed of a metal and disposed below the light emitting diode ED. Therefore, the image of the display device 100 may not be visibly recognized due to the light reflected as described above. The polarization layer polarizes the light entering from the outside to a specific direction and suppresses the reflected light from being emitted to the outside of the display device 100.

An adhesive layer Adh may be disposed between the protective layer 119 and the polarization layer 130. The adhesive layer Adh may fix the protective layer 119 and the polarization layer 130. The adhesive layer Adh minimizes foreign materials or bubbles generated between the protective layer 119 and the polarization layer 130 and uses an adhesive which is optically transparent, such as an optically clear adhesive (OCA) or an optical clear resin (OCR), but is not limited thereto.

Even though it is not illustrated, a cover member may be bonded onto the polarization layer through the adhesive layer. The adhesive layer serves to adhere the components of the display device 100 to each other, and for example, may be formed using an optically clear display adhesive, such as a pressure sensitive adhesive, an optical clear adhesive (OCA) or an optical clear resin (OCR), but is not limited thereto.

The cover member protects the component of the display device 100 from the external shocks and suppresses damages such as a scratch. For example, the cover member may be a tempered glass, but is not limited thereto.

Referring to FIG. 3 together, in the related art, the curvature is formed in the display panel using laser in the completing step of the display panel. For example, the plurality of corner areas of the display panel is formed to be rounded using a laser in the completing step of the display panel or a through-hole is formed. As the laser, picosecond laser or femtosecond laser may be used, but is not limited thereto. A laser uses stimulated emission light by amplifying the light generated by applying energy to a specific material and has characteristics similar to radio waves and has directivity to monochromatic light, so it is used for communication, medical, and industrial purposes. When the laser is used, a pattern is formed in a desired part or a specific part may be easily removed. The laser forms or removes a pattern using energy and when the energy of the laser is irradiated on a subject, the thermal energy melts the subject to form a pattern. As the time to irradiate the laser is increased, thermal effect which is transmitted near a part in which the pattern is formed may be generated. Due to this thermal effect, the heat is accumulated in the vicinity of an area of the subject on which laser is irradiated so that a surrounding area larger than a set pattern may be burned or deformed by the heat. If an area in which the laser is irradiated overlaps or is adjacent to the insulating film, due to this characteristic of the laser, the thermal energy of the laser may deform the insulating film. The insulating film is deformed to generate cracks and the cracks propagate through the insulating film so that separation occurs or permeation of the moisture or oxygen may be generated thereby. For example, there is a problem in that cracks generated when the substrate is cut using the laser propagating through the inorganic insulating layer. Moisture or oxygen propagates while reacting with the emission layer of the light emitting diode, but the cracks propagate through hard and inflexible inorganic insulating layers.

Specifically, at the top of the display panel on the encapsulation unit, the touch sensing unit including the touch buffer layer, the bridge electrode, the touch interlayer insulating layer, and the plurality of touch electrodes was disposed. However, the touch buffer layer and the touch interlayer insulating layer were formed of an inorganic insulating material which was a brittle material. Therefore, when the plurality of corner areas was formed to be rounded using the laser or a through-hole TH was formed, on the display panel, there was a problem in that cracks occurred in the touch buffer layer and the touch interlayer insulating layer included in the touch sensing unit, specifically, adjacent to the through-hole TH. Further, in order to implement a narrow bezel, when the non-display area of the display panel was bent, stresses occurred due to the bending to cause cracks in the bending area of the display panel.

Generally, after manufacturing the display device including a display panel in which a through-hole and a plurality of rounded corner areas are formed, the reliability evaluation to expose high temperature and high humidity environment is performed to confirm the stability of the product. In the related art, there was a problem in that the touch buffer layer and the touch interlayer insulating layer disposed on the dam in the non-display area were lifted due to cracks generated in the touch buffer layer and the touch interlayer insulating layer included in the touch sensing unit. There was a problem in that cracks propagated to the touch buffer layer and the touch interlayer insulating layer disposed in the display area or the touch buffer layer and the touch interlayer insulating layer disposed in the display area were lifted.

Therefore, in the display device 100 according to the exemplary embodiment of the present disclosure, instead of a layer formed of an inorganic insulating material which is a brittle material at the top of the display panel PN, the reinforcement member 120 formed of an organic insulating material is disposed. Therefore, even though the plurality of corner areas of the display panel PN is formed to be rounded or the through-hole TH is formed in the completing step of the display panel PN, the cracks generated at the top of the display panel PN and the lifted dam DAM thereby are suppressed to improve the reliability of the display device 100.

Further, in the display device 100 according to the exemplary embodiment of the present discourse, the inorganic insulating material which is a brittle material at the top of the display panel PN is removed. Therefore, even though the display panel PN is bent in the bending area BA, the stress due to the bending is reduced so that the crack in the bending area BA is also suppressed.

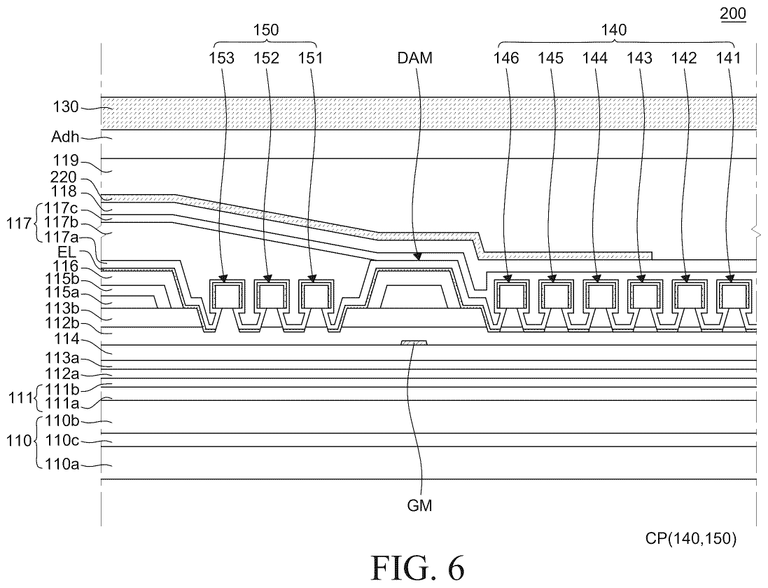

FIG. 6 is a cross-sectional view of a display device according to another exemplary embodiment of the present disclosure. As compared with the display device of FIGS. 1 to 5, only a reinforcement member 220 of a display device of FIG. 6 is different and the other configuration is substantially the same so that a redundant description will be omitted. The same configuration will be denoted with the same reference numeral. Here, the description for the same reference numeral may refer to FIGS. 1 to 5.

Referring to FIGS. 3 and 6 together, in the display device 200 according to another exemplary embodiment of the present disclosure, the reinforcement member 220 may be an organic layer including an adhesive layer or a polymer material. For example, the reinforcement member 220 may be a pressure sensitive adhesive (PSA) or polyimide. As the reinforcement member 220 which is a flexible material is disposed at the top of the display panel PN, cracks at the top layer of the display panel PN due to the external force may be suppressed.

In the display device 200 according to the exemplary embodiment of the present disclosure, when the organic layer formed of a polymer material is used as the reinforcement member 220, the reinforcement member 220 extends from the display area AA to cover the dam DAM disposed in the non-display area NA. When the organic layer formed of a polymer material is used as the reinforcement member 220, the organic layer may serve as a movement path of the moisture so that the organic layer may be disposed to be spaced apart from one end of the substrate 110 in the non-display area NA. For example, one end of the reinforcement member 220 may be located between the dam DAM and one end of the substrate 110. For example, the reinforcement member 220 may be spaced apart from one end of the display panel PN with a distance of approximately 50 μm. Further, when the organic layer formed of a polymer material is used for the reinforcement member 220, the organic layer has flexibility so that even though an external force is applied to the top layer of the display panel PN, the crack does not occur in the reinforcement member 220.

Further, in the display device 200 according to another exemplary embodiment of the present disclosure, when the organic layer formed of a polymer material is used as the reinforcement member 220, the reinforcement member 220 extends from the display area AA to cover the dam DAM disposed in the optical area OA. When the organic layer formed of a polymer material is used as the reinforcement member 220, the organic layer may serve as a movement path of the moisture so that the organic layer may be disposed to be spaced apart from the through-hole TH in the optical area OA. For example, one end of the reinforcement member 220 is located between the dam DAM and the through-hole TH and one end of the reinforcement member 220 may overlap the first prevention unit 140 which is closer to the through-hole TH than the dam DAM. For example, the reinforcement member 220 may be spaced apart from through-hole TH with a distance of approximately 50 μm. Further, when the organic layer formed of a polymer material is used for the reinforcement member 220, the organic layer has flexibility so that even though an external force is applied to the top layer of the display panel PN, the crack does not occur in the reinforcement member 220.

In the related art, at the top of the display panel on the encapsulation unit, the touch sensing unit including the touch buffer layer, the bridge electrode, the touch interlayer insulating layer and the plurality of touch electrodes was disposed. However, the touch buffer layer and the touch interlayer insulating layer were formed of an inorganic insulating material which was a brittle material. Therefore, when the plurality of corner areas was formed to be rounded using the laser or a through-hole TH was formed, on the display panel, there was a problem in that cracks occurred in the touch buffer layer and the touch interlayer insulating layer included in the touch sensing unit, specifically, adjacent to the through-hole TH. The cracks propagated through the touch buffer layer and the touch interlayer insulating layer to cause peeling or permeation of moisture and oxygen. Further, in order to implement a narrow bezel, when the non-display area of the display panel is bent, stresses occur due to the bending to cause cracks in the bending area of the display panel.

Generally, after manufacturing the display device including a display panel in which a through-hole and a plurality of rounded corner areas are formed, the reliability evaluation to expose high temperature and high humidity environment is performed to confirm the stability of the product. In the related art, there was a problem in that the touch buffer layer and the touch interlayer insulating layer disposed on the dam in the non-display area were lifted due to cracks generated in the touch buffer layer and the touch interlayer insulating layer included in the touch sensing unit. There was a problem in that cracks propagated to the touch buffer layer and the touch interlayer insulating layer disposed in the display area or the touch buffer layer and the touch interlayer insulating layer disposed in the display area were lifted.

Therefore, in the display device 200 according to another exemplary embodiment of the present disclosure, instead of a layer formed of an inorganic insulating material which is a brittle material on the uppermost end of the display panel PN, the reinforcement member 220 formed of an organic insulating material is disposed. Therefore, even though the plurality of corner areas of the display panel PN is formed to be rounded or the through-hole TH is formed in the completing step of the display panel PN, the cracks generated at the uppermost end of the display panel PN and the lifted dam DAM thereby are suppressed to improve the reliability of the display device 200.

Further, in the display device 200 according to another exemplary embodiment of the present discourse, the inorganic insulating material which is a brittle material at the top of the display panel PN is removed. Therefore, even though the display panel PN is bent in the bending area BA, the stress due to the bending is reduced so that the crack in the bending area BA is also suppressed.

Hereinafter, the effects of the present disclosure will be described in more detail with reference to Examples and Comparative Examples.

First, Example 1 in the following Table 1 is the display device 100 according to the exemplary embodiment of the present disclosure.

Example 2 in the following Table 1 is the display device 200 according to another exemplary embodiment of the present disclosure. Specifically, Example 2 has a structure in which the reinforcement member 220 is spaced apart from one end of the display panel PN.

In the meantime, Comparative Example of the following Table 1 has a different structure of a touch sensing unit located at the top of the display panel, from Example 1. That is, the display device of Comparative Example has a structure including a touch sensing unit including a touch buffer layer, a bridge electrode, a touch interlayer insulating layer, and a plurality of touch electrodes.

Stress generated on a side surface of a dam DAM disposed in the optical area OA was measured while exposing the display devices of Examples 1 and 2 and Comparative Example to a high temperature (50° C. to 100° C.) environment and a high humidity (50 to 95%) environment and the result was written in the following Table 1.

TABLE 1

| | Stress (MPa) |
|---|---|
| Example 1 | 130 |
| Example 2 | 156 |
| Comparative Example | 257 |

Referring to Table 1, as in Examples 1 and 2, instead of the layer formed of an inorganic insulating material which is a brittle material, the reinforcement members 120 and 220 formed of an organic insulating material are disposed at the top of the display panel PN. In this case, as compared with the display device of Comparative Example including a touch sensing unit including a touch buffer layer, a bridge electrode, a touch interlayer insulating layer, and a plurality of touch electrodes at the top of the display panel PN, the crack generated at the top of the display panel PN is suppressed even in the high temperature and high humidity environment. Accordingly, it is confirmed that the stress applied to the dam is reduced to suppress the lifting of the dam. Specifically, as in Example 1, it was confirmed that when the reinforcement member 120 was disposed to extend to one end of the display panel PN, the tendency of reducing stress of the dam in accordance with the reduction of cracks was clear.

The exemplary embodiments of the present disclosure can also be described as follows:

According to an aspect of the present disclosure, a display device, including a substrate which includes a display area, an optical area disposed in the display area and including a through-hole, and a non-display area enclosing the display area, a plurality of organic light emitting diodes on the display area, an encapsulation unit which covers the substrate and the plurality of organic light emitting diodes, a reinforcement member which is disposed on the encapsulation unit and extends to the display area, the non-display area, and the optical area, and a plurality of touch electrodes disposed on the reinforcement member in the display area.

The encapsulation unit may include a first encapsulation layer including an inorganic material, a second encapsulation layer which is disposed on the first encapsulation layer and includes an organic material, and a third encapsulation layer which is disposed on the second encapsulation layer and includes an inorganic material, the display device may further include an organic layer disposed on the encapsulation unit, the reinforcement member may be directly disposed on the organic layer, and the plurality of touch electrodes may be directly disposed on the reinforcement member.

The reinforcement member may include an organic layer including an adhesive layer or a polymer material.

The display device may further include a dam disposed in the non-display area or the optical area, and the reinforcement member may extend from the display area to cover the dam.

One end of the reinforcement member may extend to one end of the substrate.

One end of the reinforcement member may be spaced apart from one end of the substrate.

One end of the reinforcement member may be disposed between the dam and one end of the substrate.

The reinforcement member may extend from the display area to the through-hole.

One end of the reinforcement member may be spaced apart from the through-hole.

One end of the reinforcement member may be located between the dam and the through-hole.

The display device may further include at least one connection prevention unit which is disposed to be closer to the through-hole than the dam in the optical area and disconnects emission layers of the plurality of organic light emitting diodes, one end of the reinforcement member may overlap the connection prevention unit.

The substrate may have a plurality of rounded corner areas.

The display device may further include an optical electronic device which is disposed to overlap the optical area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate which includes a display area, an optical area in the display area and including a through-hole, and a non-display area that encloses the display area;
a plurality of organic light emitting diodes on the display area;
an encapsulation unit that covers the substrate and the plurality of organic light emitting diodes;
a reinforcement member that is on the encapsulation unit and extends to the display area, the non-display area, and the optical area; and
a plurality of touch electrodes on the reinforcement member in the display area.

2. The display device according to claim 1, wherein the encapsulation unit includes a first encapsulation layer that includes an inorganic material, a second encapsulation layer on the first encapsulation layer and includes an organic material, and a third encapsulation layer on the second encapsulation layer and includes an inorganic material,
wherein the display device further includes an organic layer on the encapsulation unit,
wherein the reinforcement member is directly on the organic layer and the plurality of touch electrodes are directly on the reinforcement member.

3. The display device according to claim 1, wherein the reinforcement member includes an organic layer including an adhesive layer or a polymer material.

4. The display device according to claim 3, further comprising:
a dam in the non-display area or the optical area,
wherein the reinforcement member extends from the display area to cover the dam.

5. The display device according to claim 4, wherein one end of the reinforcement member extends to one end of the substrate.

6. The display device according to claim 4, wherein one end of the reinforcement member is spaced apart from one end of the substrate.

7. The display device according to claim 6, wherein one end of the reinforcement member is between the dam and one end of the substrate.

8. The display device according to claim 4, wherein the reinforcement member extends from the display area to the through-hole.

9. The display device according to claim 8, wherein one end of the reinforcement member is spaced apart from the through-hole.

10. The display device according to claim 9, wherein one end of the reinforcement member is between the dam and the through-hole.

11. The display device according to claim 10, further comprising:
at least one connection prevention unit that is closer to the through-hole than the dam in the optical area and disconnects emission layers of the plurality of organic light emitting diodes,
wherein one end of the reinforcement member overlaps the at least one connection prevention unit.

12. The display device according to claim 1, wherein the substrate has a plurality of rounded corner areas.

13. The display device according to claim 1, further comprising:
an optical electronic device that overlaps the optical area.
